(19) United States
(12) Patent Application Publication
(10) Pub. No.: US 2010/0243052 A1
(43) Pub. Date: Sep. 30, 2010

(54) Sealed Photovoltaic Modules

(75) Inventors: Bruce E. Gittings, Dixon, CA (US); Daniel W. Cunningham, Mount Airy, MD (US)

Correspondence Address: CAROL WILSON;BP AMERICA INC., MAIL CODE 5 EAST, 4101 WINFIELD ROAD, WARRENVILLE, IL, 60555, US

(73) Assignee: BP Corporation North America Inc., Warrenville, IL (US)

(21) Appl. No.: 12/815,565

(22) Filed: Jun. 15, 2010

Related U.S. Application Data
(63) Continuation of application No. 10/277,324, filed on Oct. 22, 2002.
(60) Provisional application No. 60/348,255, filed on Oct. 23, 2001.

(51) Int. Cl. H01L 31/0203; H01L 31/18; H01L 31/0376; H01L 31/00

(52) U.S. Cl. 136/258; 136/259; 438/64; 136/252; 257/E31.11

(57) ABSTRACT

A sealed photovoltaic module comprising: a first substrate, a second substrate, at least one photovoltaic element positioned between the first and second substrates, and an edge seal between the first and second substrates positioned at or near an edge of and between the substrates, the edge seal comprising a moisture resistive material.

This application claims priority to and is a continuation of pending U.S. application Ser. No. 10/277,324, filed Oct. 22, 2002, which claims the benefit of U.S. Provisional Application No. 60/348,255 filed Oct. 23, 2001 and both are hereby incorporated by reference in entirety.

### FIELD OF THE INVENTION

The present invention relates to sealed photovoltaic modules and methods for their manufacture. More particularly, the present invention relates to sealed photovoltaic modules wherein a photovoltaic element is positioned between at least two substrate plates and the substrate plates are sealed near or around the edge to prevent the ingress of moisture which can permanently degrade the performance of the photovoltaic module.

### BACKGROUND OF THE INVENTION

Photovoltaic (PV) devices convert light energy, especially solar energy, into electrical energy. Photovoltaically generated electrical energy can be used for all the same purposes of electricity generated by batteries or electricity obtained from established electrical power grids, but is a renewable form of electrical energy. Sunlight is the only requirement to produce electricity using a PV device.

One type of photovoltaic device is known as a thin film device. These devices are suitably manufactured by depositing a thin, photovoltaically active layer or layers onto a suitable plate or sheet of substrate material such as glass, plastic or metal. The photovotaically active element is in the form of a thin film. This class of photovoltaic devices is referred to herein as thin film PV devices and the photovoltaic elements contained therein as thin film PV elements. Two common types of thin film photovoltaic devices have as their PV element cadmium sulfide/cadmium telluride (CdS/CdTe) films or thin amorphous silicon films. Methods for manufacturing such thin film PV elements are well known to those of skill in the art of making photovoltaic devices. After the thin film is deposited on a substrate, a second substrate is generally sandwiched to the first substrate with the thin film PV element positioned between the substrates. Generally, a polymeric material, such as poly ethyl vinyl acetate (EVA), is placed between the substrates and the substrates are heated and pressed together to form the PV module containing the PV element or elements sandwiched between the substrates. The EVA seals the substrate plates together thereby providing structural strength for the sealed module.

Another common type of photovoltaic device is a so-called crystalline or polycrystalline device. The photovoltaic elements for these types of photovoltaic devices are manufactured from wafers cut or sliced from either single crystal silicon, or polycrystalline silicon blocks, respectively. Appropriate doping of the crystalline or polycrystalline wafers imparts the photovoltaic activity to the silicon wafers. This class of photovoltaic devices is referred to herein as crystalline PV devices and the photovoltaic elements contained therein as crystalline PV elements. Again, methods for making these types of photovoltaic elements and devices are known to those of skill in the photovoltaic arts. When high voltage crystalline PV devices are desired, a number of crystalline PV elements are arranged and electrically connected on a substrate material made of transparent glass or plastic and, as with the thin film PV devices, the substrate is sandwiched with another substrate layer, generally of transparent glass or plastic, and generally with a clear polymeric-type sealing material such as EVA between the substrate layers to form a crystalline PV module. As with the thin film PV modules, the EVA seals the substrate plates together with the crystalline PV elements sandwiched between, forming a sealed module which provides for structural strength for the module. Other photovoltaic devices having different types of photovoltaic elements, such as, for example, copper indium diselenide (CIS) with or without a gallium (GIGS) or a sulfur (CISS) component, or gallium arsenide photovoltaic elements, are manufactured in a similar manner whereby the photovoltaic elements are sealed between two substrate plates using a sealing material such as EVA.

Most photovoltaic modules are used in an outdoor environment to maximize exposure to the sun. Being outdoors at all times, the module is exposed to moisture in the form of rain, humid air, fog and, depending on the location, snow, as well as other forms of atmospheric precipitation. Most photovoltaic modules will degrade in performance if moisture is allowed to come in contact with the photovoltaically active elements of the module. Such degradation is usually gradual and irreversible. High temperature may accelerate the degradation. Eventually, the photovoltaic module may experience sufficient degradation necessitating its replacement. While prior art photovoltaic devices employing the sealants such as EVA as described above can withstand exposure to moisture for certain time periods and under certain environmental conditions, the art needs improved photovoltaic modules having an improved resistance to moisture penetration. This invention provides such a photovoltaic device having an improved resistance to the ingress of moisture and, consequently, a reduction in degradation caused by exposure to moisture.

### SUMMARY OF THE INVENTION

This invention is a sealed photovoltaic module comprising: a first substrate, a second substrate, at least one photovoltaic element positioned between the first and second substrate, and an edge seal between the first and second substrates positioned at or near the edges of and between the substrates, the edge seal comprising a moisture resistive material.

### BRIEF DESCRIPTION OF THE FIGURES

FIG. 1 is a drawing of one embodiment of the sealed photovoltaic module of this invention.

FIG. 2 is the section view of the module shown in FIG. 1.

### DETAILED DESCRIPTION OF THE INVENTION

This invention is a sealed photovoltaic module. This invention is also a method for making a sealed photovoltaic module. The sealed photovoltaic module of this invention comprises a first substrate and a second substrate and at least one photovoltaic device positioned between the substrates. The substrates are spaced apart from each other and sealed to one another by a seal that, preferably, runs along the edge of or near the edge of each of the substrates. The substrates are preferably parallel to each other. The seal shields and protects the photovoltaic element within the module from exposure to water, dust and dirt, wind and other atmospheric elements and forces which would, in time, cause a deterioration of the condition and performance of the photovoltaic element contained therein.

The substrates used to form the photovoltaic modules of this invention can be glass, such as float glass, soda-lime glass or a low iron glass, a durable, strong polymeric material such as a polyimide, or a metal sheet or film such as aluminum, steel, titanium, chromium, iron, and the like. If a conductive metal is used as a substrate, it is preferable to use it in a form such that the surface of the metal substrate facing the photovoltaic device is coated with an insulating polymeric material such as a polyimide, polyester or a fluoropolymer. If one of the substrates used to make the module is opaque, such as a metal substrate, the other substrate is made of a light transmissive material such as clear glass or clear plastic. The light transmissive substrate provides for light entering the module to interact with the photovoltaic element or elements located between the substrates. Glass, particularly a highly transparent or transmissive glass, is preferred for the side of the module receiving the light to be converted into electricity, e.g., the sun's rays. The substrate is preferably flat. The substrate can be any convenient size. Generally, however, for most applications, the substrate will be made of flat glass and will range in size from about 1 square foot to about 200 square feet and will preferably be either rectangular or square in shape, although the exact shape is not limited. The thickness of the substrate is also variable and will, in general, be selected in view of the application of the module. If, for example, the module uses glass as the substrate, the thickness of the glass can range in thickness from 0.08 inches to about 0.500 inches, more preferably from about 0.125 inches to about 0.250 inches. If the glass will be used in large dimensions, such as for example, at least about 60, or at least about 200 square feet, the glass will preferably have a thickness of at least about 0.125 inches, more preferably of at least about 0.187 inches. When the glass substrate has a thickness of at least about 0.187 inches or at least about 0.250 inches, it will preferably be a low iron glass. By low iron we mean, preferably, that the glass has no more than about 0.1 wt % iron, more preferably less than about 0.1 wt % iron.

The photovoltaic element, whether it is a thin film amorphous silicon PV element, a thin film CdS/CdTe PV element, an array of crystalline PV elements or some other photovoltaic element, is positioned between the substrates in the module of this invention. The edge seal in the PV module of this invention is a film of moisture resistive material preferably positioned around the perimeter of the substrate and located between the substrates and in contact with each substrate thereby forming a seal that seals the edges of the substrate to each other. The thickness of the seal will depend on the thickness of the photovoltaic elements placed between the substrate plates and will also depend on whether an encapsulant material such as EVA, as described in detail below, is also used. In general, however, the edge moisture resistive seal of this invention has a thickness of about 0.01 inch to about 0.2 inch, more preferably about 0.015 to about 0.04 inch, and most preferably about 0.018 to about 0.025 inch.

In the preferred embodiment of this invention, the edge seal is in the form of a strip that is located between the substrates and around or near the perimeter of the substrates. Generally, the edge seal is wide enough to prevent the ingress of moisture into the photovoltaic module, that is ingress or penetration of moisture into the PV elements located between the substrates. For example, the strip should be wide enough to provide for sufficient adhesion to the substrate surfaces thereby forming a seal to the substrate surfaces for preventing the passage of moisture between the edge seal and the substrates. The seal should be sufficiently wide such that the module can withstand treatment at 85° C. in air with a relative humidity of 85% for 1000 hours with a performance degradation of no more than about 20%, preferably no more than about 15%, more preferably no more than about 10% and most preferably no more than about 5%. Generally, the width of the edge seal will be about 0.25% to about 20%, preferably about 0.5% to about 10%, and more preferably about 1% to about 5% of the largest dimension of the substrate. For many applications, the edge seal may have a width of about 0.1 to about 2 inches, preferably about 0.4 to about 1 inch. It is to be understood that the preferred embodiment of this invention is to have the edge seal extend or run completely along the perimeter of the substrates and between the substrates. However, one or more portions of the perimeter of the substrate and thus the finished module can be without the edge seal of this invention.

The edge seal is preferably made of a material that is highly resistive to moisture penetration. That is, it is made of a material that will not allow significant amounts of water to pass through the material. The edge seal material is preferably a material that will form a tight seal with the substrate material such that no path exists for moisture to penetrate into the PV element along the interface between the edge seal and the substrate. It is preferably a solid or at least a semi-solid material at the temperatures of operation for a PV module, such as a temperature from about −40° C. to about 90° C., and is preferably a material that will soften at elevated temperatures, such as about 120° C. to about 170° C., more preferably about 140° C. to about 160° C., so that it will form a tight, moisture resistant seal with the substrate materials when it is heated to such temperatures for application to the substrates. Synthetic polymer and natural rubber materials are highly satisfactory as the material for the edge seal in the module of this invention. For example, butyl rubber, urethane and polyurethane materials, polyisobutylene materials, epoxides that are liquid or semi-solid in the uncured state at ambient temperature and solid in the cured state, UV curable polysulfamides and cyanoacrylates. The rubber and polymeric materials used for the edge seal of this invention may also be mixtures of one or more rubbers or polymeric materials and may also contain fillers, stabilizers and other materials added to improve the oxidative, heat and UV resistance of the material. Most preferably, the material used for making the edge seal in the module of this invention comprises butyl rubber that is a solid at temperatures of about −40° C. to about 95° C. and has a softening point of about 130° C. to about 160° C. so that when it is heated at such temperatures it softens to form a moisture resistant seal with the substrate materials of the PV module.

Preferably, the edge seal material prior to application is in the form of a tape or strip that can be placed in the appropriate location on the substrate prior to adding the second substrate.

The material used for the edge seal may contain one or more desiccants to actively absorb and retain moisture. While the sealant material on its own should be highly impermeable to moisture penetration, the edge sealant material may contain an active desiccant agent to absorb and retain any moisture that may penetrate the sealant material. Such dessicant materials include components that absorb or adsorb water molecules such as molecular sieves or zeolite materials, dehydrated clays, silicates, aluminosilicates, and the like. It can also be a material that chemically reacts with water such as inorganic or organic anhydrides, or anhydrous compounds. These chemical agents can be mixed in with the sealant material or can be grafted to the polymer chains in the sealant material. Other desiccant agents include chemical compounds such as calcium chloride or magnesium sulfate that form hydration complexes with water molecules. Any such water absorbing or adsorbing material can be used. The amount of desiccant material in the edge sealant material will vary depending on the efficacy of the material and its effect on the physical properties of the sealant material. However, generally, the edge sealant material will contain about 0.1% to about 10% by weight desiccant, if a desiccant is used.

Preferably, the moisture resistance of the material used to form the edge seal of the module of this invention has a Moisture Vapor Transmission Rate (MVTR) no more than about 5, preferably no more than about 1, more preferably no more than about 0.5, and most preferably no more than about 0.3 as measured by the ASTM Standard [F-1249]. The units for this measurement are grams of water per square meter per 24 hours using a 0.060 inch thick sheet of test material.

A suitable source of butyl rubber sealant material is available from TruSeal Technologies, Inc. located in Beachwood, Ohio. One such butyl rubber material is Grey Desiccated Butyl Extrusion.

In the PV modules of this invention it is preferred to have an encapsulant such as EVA and the like, placed between the substrates and covering the PV elements. An encapsulant provides for the protection of the PV element, adds structural strength to the module by adhering the substrates together to form the module. In its preferred embodiment, it is to be understood that the moisture impermeable edge sealant of the module of this invention is separate from and in addition to the encapsulant, if such encapsulant is used. That is, in the preferred embodiment, the edge seal is placed around or near the perimeter of the substrates whereas the encapsulant, if used, generally covers the PV element or elements contained between the substrates. The encapsulant generally has a thickness of about 0.01 to about 0.2 inch, more preferably about 0.015 to about 0.1 inch.

Methods for making PV elements useful in the module of this invention are known to those of skill in the art. For example, methods for making CdS/CdTe PV elements and PV devices are described in N. R. Pavaskar, et al., J. Electrochemical Soc. 124 (1967) p. 743; I. Kaur, et al., J. Electrochem Soc. 127 (1981) p. 943; Panicker, et al., “Cathodic Deposition of CdTe from Aqueous Electrolytes,” J. Electrochem Soc. 125, No. 4, 1978, pp. 556-572, U.S. Pat. No. 4,400,244; EP Patent 244963; U.S. Pat. No. 4,548,681; EP Patent 0538041; U.S. Pat. No. 4,388,483; U.S. Pat. No. 4,735,662; U.S. Pat. No. 4,456,630; U.S. Pat. No. 5,472,910; U.S. Pat. No. 4,243,432; U.S. Pat. No. 4,383,022, “Large Area Apollo® Module Performance and Reliability” 28^{th} IEEE Photovoltaic Specialists Conference, Anchorage, Ala., September 2000; all of which are incorporated by reference herein. Also incorporated by reference is U.S. Provisional Patent Application 60/289,481 filed on May 8, 2001.

Methods for manufacturing amorphous silicon thin film PV elements useful in the sealed module of this invention are described in, for example, U.S. Pat. No. 4,064,521, U.S. Pat. No. 4,292,092, UK Patent Application 9916531.8 (Publication No. 2339963), Feb. 9, 2000, U.S. Pat. No. 5,593,901, U.S. Pat. No. 4,783,421, U.S. Pat. No. 6,121,541, all of which are incorporated by reference herein. Also incorporated by reference is U.S. patent application Ser. No. 09/891,752 filed on Jun. 26, 2001.

Suitable crystalline and polycrystalline PV elements are manufactured by BP Solar International LLC of Linthicum, Md., and by Siemens and Shell Solar GmbH. Preferably, the PV element or element in the modules of this invention are the CdS/CdTe type of thin film PV elements.

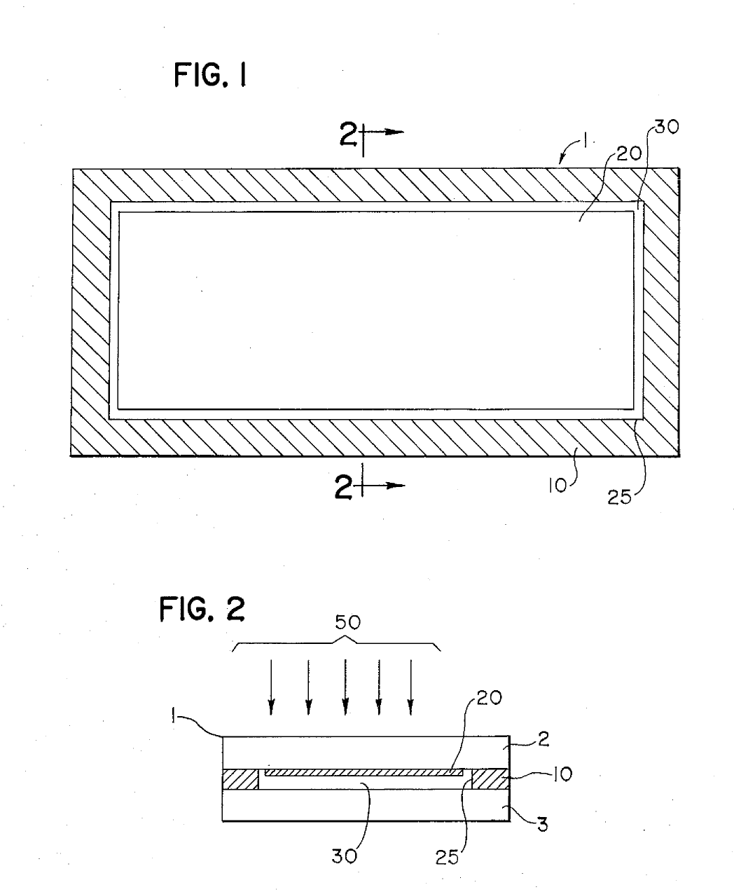

Embodiments of the invention will now be described in view of FIGS. 1 and 2.

FIG. 1 is a top view of one embodiment of the invented PV module. FIG. 2 is a side view of the invented module taken along the section shown in FIG. 1. The same elements in each Figure are numbered the same for ease of understanding.

FIG. 1 shows module 1 and edge seal 10 as a strip of sealant material located around the perimeter of the module. As shown in FIG. 2, edge sealant 10 is located between front substrate 2 and back substrate 3, and edge sealant 10 is in direct contact with both the front substrate 2 and back substrate 3, forming an excellent seal around the perimeter of the module 1. Photovoltaic element 20 is positioned between substrates 2 and 3 as shown in FIGS. 1 and 2. The PV element 20 can be any type of PV element such as a thin film element such as a CdS/CdTe PV element, an amorphous silicon element, or it can be one or more crystalline PV elements. FIGS. 1 and 2 also show encapsulant 30 positioned on PV element 20 and sealed to substrates 2 and 3. Light rays 50 show the side of the module that is exposed to solar or other light radiation for conversion to electricity by the photovoltaic module 1.

Front substrate 2 and back substrate 3 are preferably glass, preferably flat and highly transmissive glass. However, back substrate 3 does not necessarily need to be a light transmissive material. Back substrate 3 can be, for example, metal or a laminate such as TAP (Tedlar, aluminum, polyester laminate available from Isovolta AG, Wiener Neudorf, Austria). Encapsulant 30 is preferably EVA. Edge seal 10 is preferably a desiccated butyl rubber such as TruSeal's Grey Butyl Desiccated Extrusion rubber. This material contains a desiccant. While the interface 25 between edge seal 10 and PV sealant 30 is shown in FIGS. 1 and 2 as a straight line, it is to be understood that such interlace does not necessarily have to be as such. The interface can be formed by overlapping edge seal 10 and PV seal 30 so that the actual interface may have more of an overlapping-type of configuration. PV modules generally have a conductor means for connecting the module to the device or system to which the PV will supply electricity. Such conductor means vary according to the type of module and type PV element used therein. FIGS. 1 and 2 do not show such conductor means but it is understood by those of skill in the art that such conductor means are present in PV modules. It is to be understood that the module of FIGS. 1 and 2 can have a reversed layer arrangement in that, depending on which is the active side of the PV element, the light 50 can enter the module from the same side of the module as substrate 3. In such a reversed arrangement, the light will pass through encapsulant 30 before impinging on PV element 20.

In the preferred method for making the modules of this invention, a suitable

PV element or elements (any type of PV element such as, for example, a thin film element or a crystalline element) are placed on a flat, clear glass first substrate. The PV elements are positioned or deposited on the first substrate so that they do not extend to the edge of the first substrate thereby leaving a border of glass around the entire perimeter of the first substrate. An encapsulant, such as EVA, in the form of a sheet is positioned on a second substrate. The second substrate is preferably made of flat, transmissive glass of approximately the same size as the first substrate. The size and position of the encapsulant material on the second sheet is such that when the first substrate and the second substrate are placed together sandwiching the PV element or elements and the encapusalant material between the substrates, the encapsulant covers the PV elements but leaves a border of uncovered substrate around the perimeter of the substrates. The edge seal, preferably in the form of a tape, placed around the perimeter of the second substrate so that the inside edge of the edge seal, relative to the location of the sheet of encapsulant, is next to or spaced slightly from the edge of the sheet of encapsulant, and the outside edge of the edge sealant is at or close to the edge of the second substrate. The first substrate containing the PV element and the second substrate containing the encapsulant and edge seal are placed together forming a sandwich or layer structure with the PV element, encapsulant and edge seal between the substrates. The sandwich or layer structure so formed is heated to a temperature suitably of about 140° C. to about 160° C., that will soften the seal materials, and the entire assembly is pressed together at the elevated temperature, optionally in a vacuum chamber to preclude the formation of air pockets of bubbles between the substrates, and to form the sealed module of this invention.

The modules of this invention show highly effective resistance to the ingress or penetration of moisture to the PV elements located within the sealed module. One effective method for measuring the resistance to moisture penetration is to submit the finished module to an accelerated moisture resistance test as set forth in the

International Electrical Commission (IEC) 1215 International Standard, or an equivalent test procedure. In this test procedure, the electrical characteristics of a module are first measured under standard conditions such as one (1) sun of illumination at a module temperature of about 25° C. The module is subsequently exposed to humid air at an elevated temperature for 1000 hours. The humid air has a relative humidity of about 85% and the air temperature is about 85° C. During this testing, the module, if it is susceptible to moisture penetration and the resulting degradation of module performance, will experience a decrease in electrical characteristics relative to the module before accelerated testing when measured again under standard conditions. The electrical characteristics typically measured are maximum power, short-circuit current, open-circuit voltage, efficiency and fill-factor.

When tested according to the IEC method described above or equivalent method, the modules of this invention exhibit a decrease in power output of no more than about 20%, preferably no more than about 15%, more preferably no more than about 10% and most preferably no more than about 5%. The decrease in power output of the modules of this invention can be no more than about 2% when tested according to these procedures. Thus, the sealed modules of this invention are highly effective at resisting the ingress or penetration of moisture into the photovoltaically active elements of the photovoltaic module.

The following examples describe certain embodiments of the above-described invention but are not to be construed as limiting in any way the scope thereof.

### Example 1

This example used a 2 ft. by 5 ft. flat glass “front” substrate having a CdS/CdTe photovoltaic element deposited thereon so that the thin film PV element covered the surface of the substrate except for a 0.5 inch border around the PV element. A sheet of EVA having a thickness of 0.018 inch was positioned on a second front glass substrate, i.e., “back” substrate, of approximately the same dimension as the front substrate. The EVA was positioned so that there was a 0.625 inch wide glass border of each edge of the second (back) substrate. Strips measuring 0.5 inches wide and 0.021 inches thick of Grey Desiccated Butyl Extrusion rubber obtained from Tru Seal Industries, Inc., were positioned on the back substrate next to the EVA sheet around the perimeter of the back substrate so that the strips were about 0.125 inch from the EVA and about flush with the edge of the back substrate. The two substrates were placed together with the sealed materials and PV elements facing each other. The resulting sandwich assembly was heated at approximately 160° C. for about seven minutes under a vacuum while simultaneously and uniformly pressing the substrate plates together to form the module. Electrical leads from the PV element exited the module through two small holes in the back substrate. The holes were subsequently filled with a pottant to seal the holes.

### Example 2 (Comparative Example)

A PV module was prepared according to the procedure of Example 1 except that the EVA sheet was placed across the entire surface of the second substrate and no butyl rubber tape was added.

### Example 3

The PV modules from Examples 1 and 2 were tested for their resistance to moisture penetration using the IEC test described above. The module of Example 1 showed only a 4.5% decrease in power output while the PV module of Example 2 showed a 35% decrease in power output. These results show the superior moisture resisting performance of the invented modules. Other modules made in a manner as described in Example 1 showed a decrease in performance ranging from 2% to 13%. Most, however, showed a decrease in performance at about 5%. The value of 13% obtained is believed to be due to factors other than moisture penetration.

The provisional patent application 60/348,255 filed on Oct. 23, 2001, is incorporated by reference herein in its entirety.

Having described the invention, that which is claimed is:

1. A sealed photovoltaic module comprising: a first substrate, a second substrate, at least one photovoltaic element positioned between the first and second substrates, and an edge seal between the first and second substrates positioned at or near an edge of and between the substrates, the edge seal comprising a moisture resistive material.

2. The sealed photovoltaic module of claim 1 wherein the edge seal extends around the perimeter of the module.

3. The sealed photovoltaic module of claim 2 wherein the edge seal is in the form of a strip located between the substrates.

4. The sealed photovoltaic module of claim 2 wherein the edge seal comprises butyl rubber.

5. The sealed photovoltaic module of claim 2 wherein the edge seal comprises a dessicant.

6. The sealed photovoltaic module of claim 2 wherein the edge seal comprises a material having an MVTR of no more than about 5.

7. The module of claim 2 wherein at least one photovoltaic element comprises a thin film CdS/CdTe element.

8. The module of claim 2 wherein at least one photovoltaic element comprises a thin film amorphous silicon element.

9. The module of claim 2 further comprising an encapsulant.

10. A photovoltaic module having a reduction in power output of no more than about 20% when measured using IEC 1215 International Standard.

11. The sealed photovoltaic module of claim 10 wherein the reduction in power output is no more than about 10%.

12. A photovoltaic module comprising an edge seal and an encapsulant.

13. The photovoltaic module of claim 12 where the edge seal comprises a material comprising butyl rubber.

14. The photovoltaic module of claim 13 wherein the edge seal extends completely around the perimeter of the photovoltaic module.

15. A method for making a sealed photovoltaic module comprising (a) positioning between two substrate plates at least one photovoltaic element and an edge seal, the edge seal positioned at or near the perimeter of the substrates and (b) joining the substrate plates so that the edge seal forms a seal along the perimeter of the substrate plates sealing the substrate plates together.

16. The method of claim 15 further comprising positioning an encapsulant between the substrate plates.

17. The method of claim 15 wherein the edge sealant is in the form of a strip.

18. The method of claim 15 wherein the substrate plates are heated while joining the substrate plates.

19. The method of claim 15 wherein the edge seal comprises butyl rubber.

20. The method of claim 19 wherein the edge seal comprises a desiccant.
